(19) United States
(12) Patent Application Publication
(10) Pub. No.: US 2012/0147690 A1
(43) Pub. Date: Jun. 14, 2012

(54) MEMORY ACCESSING DEVICE

(75) Inventor: Koji Tainaka, Katano-shi (JP)

(73) Assignee: SANYO ELECTRIC CO., LTD., Osaka (JP)

(21) Appl. No.: 13/311,985

(22) Filed: Dec. 6, 2011

(30) Foreign Application Priority Data
Dec. 13, 2010 (JP) 2010-276730

(51) Int. Cl. G11C 8/06; G11C 8/00

(52) U.S. Cl. 365/230.08; 365/230.01

(57) ABSTRACT

A memory accessing device includes a generator which generates K (K: an integer equal to or more than two) of address coefficients corresponding to a first mode whereas generates L (L: an integer more than K) of address coefficients corresponding to a second mode. A first converter converts each value of the address coefficients generated by the generator into a value of 1/M (M: an integer equal to or more than two). A creator creates address information based on the address coefficients generated by the generator corresponding to the first mode whereas creates address information based on address coefficients converted by the first converter corresponding to the second mode. An outputter outputs the address information created by the creator in order to access a memory provided with a plurality of addresses each of which has a bit width equivalent to any one of N bits and N/M bits.

### CROSS REFERENCE OF RELATED APPLICATION

The disclosure of Japanese Patent Application No. 2010-276730, which was filed on Dec. 13, 2010, is incorporated here by reference.

### BACKGROUND OF THE INVENTION

1. Field of the Invention

The present invention relates to a memory accessing device. More particularly, the present invention relates to a memory accessing device which generates address information for accessing memories each of which has a different bit width.

2. Description of the Related Art

According to one example of this type of device, a read timing control circuit changes a read address to be applied to a memory in the middle of one read cycle. A latch circuit latches data read out from the memory before the read address is changed. A data bus transfers, in parallel, the data latched by the latch circuit and the data read out from the memory after the read address has been changed. Therefore, it is possible to improve an efficiency of a data reading operation from a memory having a bus width which is smaller than a data bus width.

### SUMMARY OF THE INVENTION

A memory accessing device according to the present invention, comprises: a generator which generates K (K: an integer equal to or more than two) of address coefficients corresponding to a first mode whereas generates L (L: an integer more than K) of address coefficients corresponding to a second mode; a first converter which converts each value of the address coefficients generated by the generator into a value of 1/M (M: an integer equal to or more than two); a creator which creates address information based on the address coefficients generated by the generator corresponding to the first mode whereas creates address information based on address coefficients converted by the first converter corresponding to the second mode; and an outputter which outputs the address information created by the creator in order to access a memory provided with a plurality of addresses each of which has a bit width equivalent to any one of N bits and N/M bits.

According to the present invention, a memory accessing method which is executed by a memory accessing device, comprises: a generating step of generating K (K: an integer equal to or more than two) of address coefficients corresponding to a first mode whereas generating L (L: an integer more than K) of address coefficients corresponding to a second mode; a first converting step of converting each value of the address coefficients generated by the generating step into a value of 1/M (M: an integer equal to or more than two); a creating step of creating address information based on the address coefficients generated by the generating step corresponding to the first mode whereas creating address information based on address coefficients converted by the first converting step corresponding to the second mode; and an outputting step of outputting the address information created by the creating step in order to access a memory provided with a plurality of addresses each of which has a bit width equivalent to any one of N bits and N/M bits.

The above described features and advantages of the present invention will become more apparent from the following detailed description of the embodiment when taken in conjunction with the accompanying drawings.

### BRIEF DESCRIPTION OF THE DRAWINGS

FIG. 1 is a block diagram showing a basic configuration of one embodiment of the present invention;

FIG. 2 is a block diagram showing a configuration of one embodiment of the present invention;

FIG. 3 is a block diagram showing one embodiment of a configuration of an address designating circuit applied to the embodiment in FIG. 2;

FIG. 4 is a block diagram showing one embodiment of a configuration of an address converting circuit applied to the embodiment in FIG. 2;

FIG. 5(A) is a wave form chart showing one embodiment of a clock CLK1;

FIG. 5(B) is a wave form chart showing one embodiment of a clock CLK2;

FIG. 5(C) is an illustrative view showing one embodiment of an output of a counter 24;

FIG. 5(D) is an illustrative view showing one embodiment of an output of a counter 32;

FIG. 5(E) is an illustrative view showing one embodiment of an integrated address outputted from an F/F circuit 36;

FIG. 5(F) is an illustrative view showing one embodiment of a column address outputted from an F/F circuit 58;

FIG. 5(G) is an illustrative view showing one embodiment of data inputted from a bus;

FIG. 5(H) is an illustrative view showing one embodiment of data outputted to an SDRAM;

FIG. 5(I) is an illustrative view showing one embodiment of data inputted from the SDRAM;

FIG. 5(J) is an illustrative view showing one embodiment of data outputted to the bus;

FIG. 6(A) is a wave form chart showing one embodiment of the clock CLK1;

FIG. 6(B) is a wave form chart showing one embodiment of the clock CLK2;

FIG. 6(C) is an illustrative view showing one embodiment of an output of the counter 24;

FIG. 6(D) is an illustrative view showing one embodiment of an output of the counter 32;

FIG. 6(E) is an illustrative view showing one embodiment of the integrated address outputted from the F/F circuit 36;

FIG. 6(F) is an illustrative view showing one embodiment of the column address outputted from the F/F circuit 58;

FIG. 6(G) is an illustrative view showing one embodiment of the data inputted from the bus;

FIG. 6(H) is an illustrative view showing one embodiment of the data outputted to the SDRAM;

FIG. 6(I) is an illustrative view showing one embodiment of the data inputted from the SDRAM;

FIG. 6(J) is an illustrative view showing one embodiment of the data outputted to the bus;

FIG. 7 is a block diagram showing one embodiment of a configuration of a write data transfer circuit applied to the embodiment in FIG. 2;

FIG. 8(A) is a wave form chart showing one embodiment of the clock CLK1;

FIG. 8(B) is an illustrative view showing one embodiment of data inputted from the bus;

FIG. 8(C) is an illustrative view show,* one embodiment of data outputted from an F/F circuit 60;

FIG. 8(D) is an illustrative view showing one portion of data outputted from a selector 116;

FIG. 8(E) is a wave form chart showing one embodiment of the clock CLK2;

FIG. 8(F) is an illustrative view showing one embodiment of data read from an SRAM 92;

FIG. 8(G) is an illustrative view showing one embodiment of data outputted from an F/F circuit 94;

FIG. 8(H) is an illustrative view showing another portion of the data outputted from the selector 116;

FIG. 8(I) is an illustrative view showing one embodiment of data outputted to the SDRAM;

FIG. 9(A) is a wave form chart showing one embodiment of the clock CLK1;

FIG. 9(B) is an illustrative view showing one embodiment of the data inputted from the bus;

FIG. 9(C) is an illustrative view showing one embodiment of the data outputted from the F/F circuit 60;

FIG. 9(D) is an illustrative view showing one embodiment of the data outputted to the SDRAM;

FIG. 10 is a block diagram showing one embodiment of a configuration of a read data transfer circuit applied to the embodiment in FIG. 2;

FIG. 11(A) is a wave form chart showing one embodiment of the clock CLK1;

FIG. 11(B) is an illustrative view showing one embodiment of data inputted from the SDRAM;

FIG. 11(C) is an illustrative view showing one embodiment of data outputted from a combiner 134;

FIG. 11(D) is an illustrative view showing one embodiment of data read out from an SRAM 136;

FIG. 11(E) is an illustrative view showing one portion of data outputted from a selector 200;

FIG. 11(F) is an illustrative view showing another portion of the data outputted from the selector 200;

FIG. 11(G) is an illustrative view showing one portion of data outputted to the bus;

FIG. 12(A) is a wave form chart showing one embodiment of the clock CLK1;

FIG. 12(B) is an illustrative view showing one embodiment of data inputted from the SDRAM; and

FIG. 12(C) is an illustrative view showing one embodiment of data outputted to the bus.

### DETAILED DESCRIPTION OF THE PREFERRED EMBODIMENTS

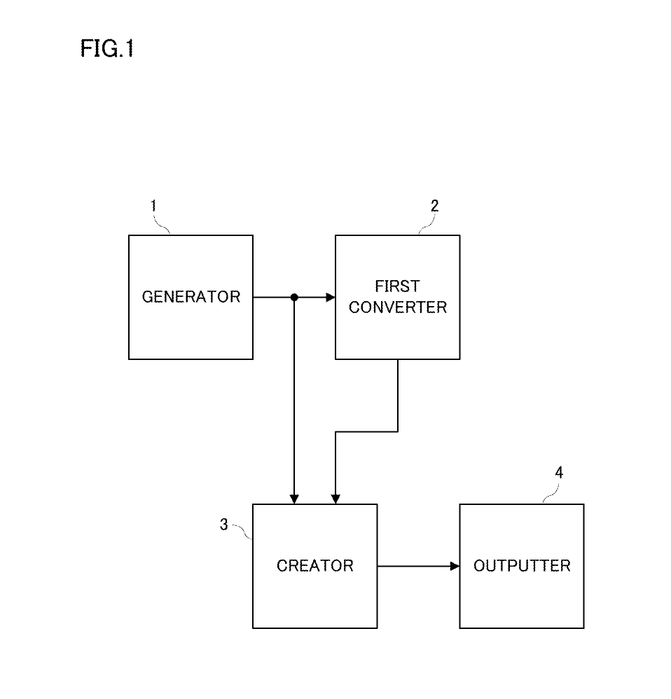

With reference to FIG. 1, a memory accessing device according to one embodiment of the present invention is basically configured as follows: A generator 1 generates K (K: an integer equal to or more than two) of address coefficients corresponding to a first mode whereas generates L (L: an integer more than K) of address coefficients corresponding to a second mode. A first converter 2 converts each value of the address coefficients generated by the generator 1 into a value of 1/M (M: an integer equal to or more than two). A creator 3 creates address information based on the address coefficients generated by the generator 1 corresponding to the first mode whereas creates address information based on address coefficients converted by the first converter 2 corresponding to the second mode. An outputter 4 outputs the address information created by the creator 3 in order to access a memory provided with a plurality of addresses each of which has a bit width equivalent to any one of N bits and N/M bits.

Under the first mode, the address information is created based on the K of address coefficients generated by the generator 1. In contrast, under the second mode, each value of the L of address coefficients generated by the generator 1 is converted to a value of 1/M, and the address information is created based on the L of address coefficients each of which indicates the converted value. On the other hand, each address of the memory has a bit width equivalent to any one of the N bits and N/M bits.

Accordingly, by selecting the first mode for a memory having a bit width equivalent to the N bits and selecting the second mode for a memory having a bit width equivalent to the N/M bits, an adoptive accessing operation is realized for memories each of which has a different bit width, and therefore, memory access performance is improved.

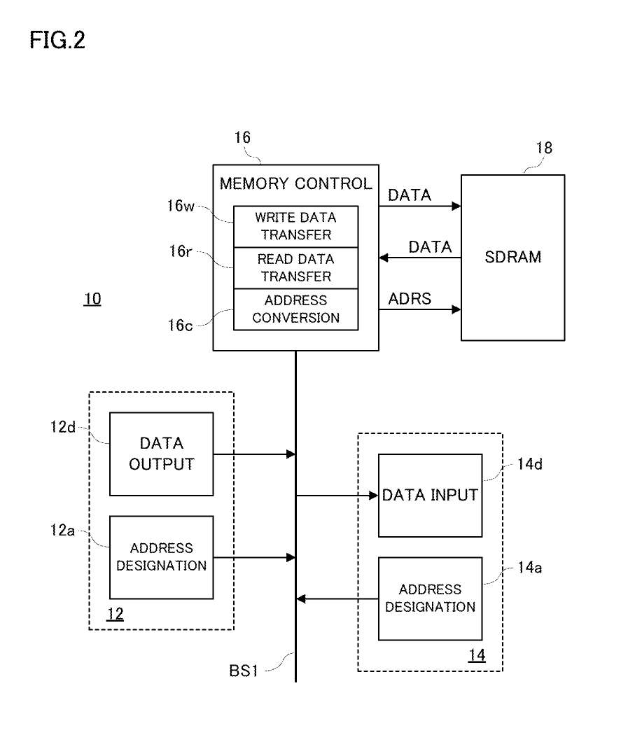

With reference to FIG. 2, a data processing apparatus 10 according to one embodiment includes a data processing circuit 12 which takes a role in data writing and a data processing circuit 14 which takes a role in data reading. The data processing circuit 12 is formed of an address designating circuit 12a and a data outputting circuit 12d, and the data processing circuit 14 is formed of an address designating circuit 14a and a data inputting circuit 14d.

The address designation circuit 12a generates integrated addresses of which number is different depending on a bit width of an SDRAM 18 in a manner different depending on the bit width of the SDRAM 18. The integrated addresses generated are applied to an address converting circuit 16c of a memory control circuit 16 via a bus BS1. On the other hand, the data outputting circuit 12d repeatedly outputs data having a 32 bit width for each word, 16 words at a time. The outputted data is applied to a write data transfer circuit 16w of the memory control circuit 16 via the bus BS1.

Here, a bank address, a row address and a column address of an access destination are described in the integrated address. Furthermore, the SDRAM 18 adopts a burst access system, and each of a plurality of addresses provided in the SDRAM 18 has a 16 bit width or a 32 bit width. In case the SDRAM 18 is a memory adopting the 16 bit width, eight integrated addresses are generated from the address designating circuit 12a corresponding to a single burst access. On the other hand, in case the SDRAM 18 is a memory adopting the 32 bit width, four integrated addresses are generated from the address designating circuit 12a corresponding to the single burst access.

The address converting circuit 16c detects the bank address, the row address and the column address which are described in the integrated address, and outputs the detected bank address, row address and column address to the SDRAM 18. Here, a value of the column address is adjusted with referring to the bit width of the SDRAM 18.

In case the SDRAM 18 adopts the 16 bit width, the write data transfer circuit 16w converts data (the data is equivalent to 16 words each having a 32 bit width) applied from the bus BS1 into data equivalent to 32 words each having a 16 bit width, and outputs the converted data to the SDRAM 18. In contrast, in case the SDRAM 18 adopts the 32 bit width, the write data transfer circuit 16w outputs the data applied from the bus BS1 to the SDRAM 18 as it is. Thus outputted data is written into an address designated by the address converting circuit 16c.

The address designating circuit 14a provided in the data processing circuit 14 also generates integrated addresses of which number is different depending on the bit width of the SDRAM 18 in a manner different depending on the bit width of the SDRAM 18. Similarly to the above description, in case the SDRAM 18 adopts the 16 bit width, eight integrated addresses are generated from the address designating circuit 14a. On the other hand, in case the SDRAM 18 adopts the 32 bit width, four integrated addresses are generated from the address designating circuit 14a.

The generated integrated addresses are applied to the address converting circuit 16c via the bus BS1, and a bank address, a row address and a column address based thereon are outputted to the SDRAM 18 as described above. Consequently, data stored in the designated address is read out.

In case the SDRAM 18 is an SDRAM adopting the 16 bit width, data having a 16 bit width for each word is read out by 32 words. On the other hand, in case the SDRAM 18 is an SDRAM adopting the 32 bit width, data having a 32 bit width for each word is read out by 16 words.

When the SDRAM 18 is the memory adopting the 16 bit width, the read data transfer circuit 16r converts the read data (the read data is equivalent to the 32 words each having the 16 bit width) into data equivalent to 16 words each having the 32 bit width, and outputs the converted data to the bus BS1. In contrast, if the SDRAM 18 is the memory adopting the 32 bit width, the read data transfer circuit 16r outputs the read data to the bus BS1 as it is. The data passed through the bus BS1 is thereafter taken in the data inputting circuit 14d.

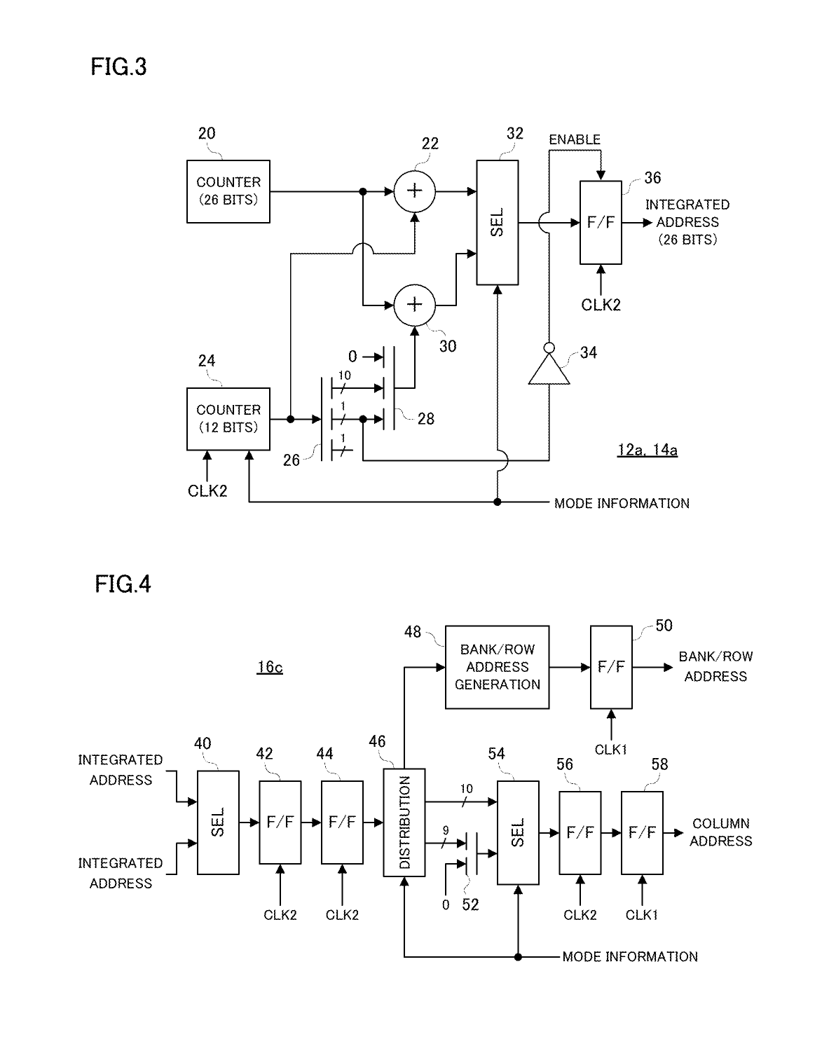

Each of the address designating circuits 12a and 14a is configured as shown in FIG. 3. A counter 20 generates a count value of 26 bits in upper 14 bits of which a part of the bank address and a part of the row address are described. On the other hand, a counter 24 generates a count value of 12 bits in which a part of the bank address, a part of the row address, and the column address are described, by times which is different depending on a mode indicated by mode information.

The mode information indicates “MD16” in case the SDRAM 18 is the memory adopting the 16 bit width, and indicates “MD32” in case the SDRAM 18 is the memory adopting the 32 bit width. The counter 24 outputs a total of 15 count values which is incremented by two from “0” to “28” in response to rising of a clock CLK2, when the mode information indicates “MD16”. The counter 24 also outputs a total of 7 count values which is incremented by two from “0” to “12” in response to rising of the clock CLK2, when the mode information indicates “MD32”.

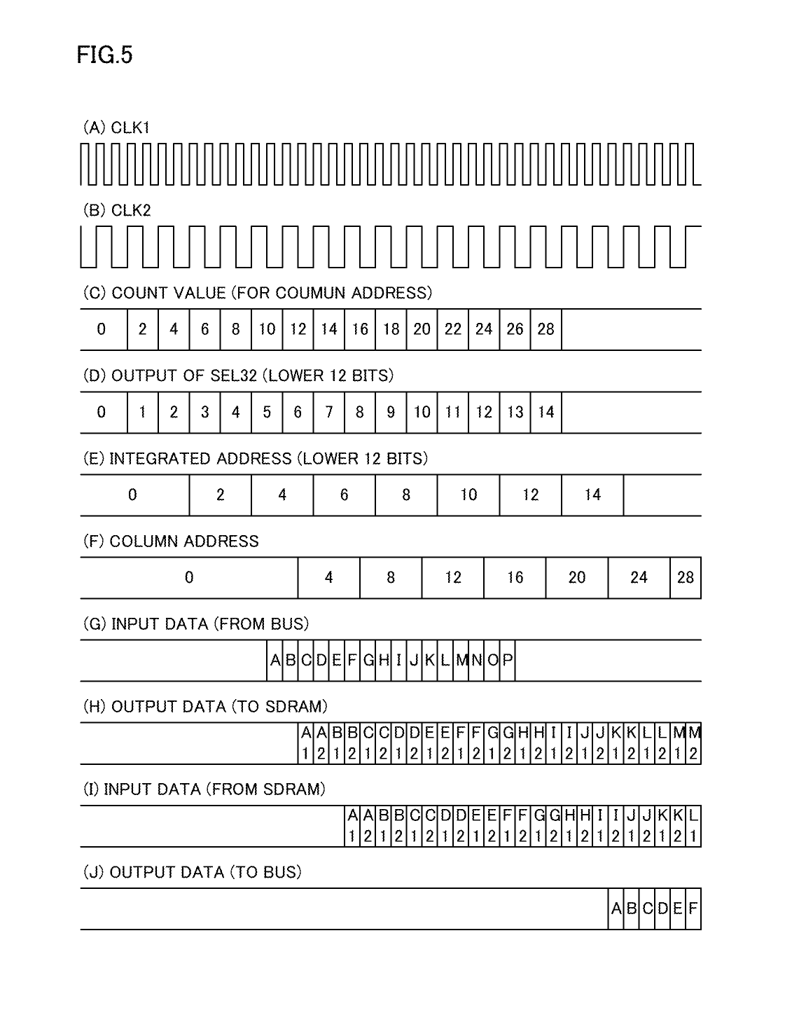

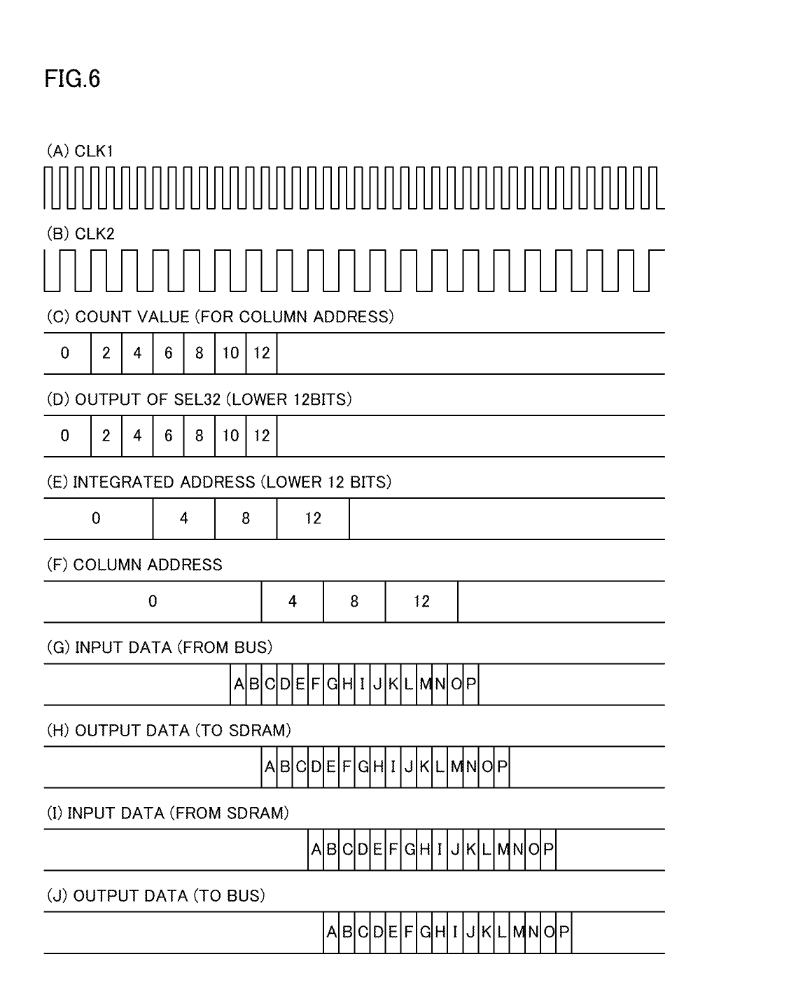

Accordingly, in case the SDRAM 18 adopts the 16 bit width, the count value is outputted in a manner shown in FIG. 5(C) in synchronization with the clock CLK2 shown in FIG. 5(B). In contrast, in case the SDRAM 18 adopts the 32 bit width, the count value is outputted in a manner shown in FIG. 6(C) in synchronization with the clock CLK2 shown in FIG. 6(B). It is noted that a period of the clock CLK2 is twice the period of a clock CLK1 shown in FIG. 5(A) or FIG. 6(A).

An adder 22 adds together two count values which are respectively outputted from the counters 20 and 24 so as to apply thus obtained added value to one input terminal of a selector 32. An adder 30 adds together the count value outputted from the counter 20 and a below described 12 bit value outputted from a combiner 28 so as to apply thus obtained added value to another input terminal of the selector 32.

A distributor 26 divides the count value outputted from the counter 24 into a value of upper 10 bits, a value of the second bit from the bottom, and a value of the least significant bit. Out of these values, the value of upper 11 bits is applied to the combiner 28, the value of the second bit from the bottom is applied to an F/F circuit 36 via an inverter 34, and the value of the least significant bit is abolished. The combiner 28 appends one bit value indicating “0” to the top of the 11 bit value applied from the distributor 26 so as to apply thus obtained 12 bit value(=one half of the count value outputted from the counter 24) to the adder 30.

The selector 32 selects the added value outputted from the adder 30 when the mode information indicates “MD16” and selects the added value outputted from the adder 22 when the mode information indicates “MD32”. Accordingly a value of lower 12 bits of the added value selected by the selector 32 changes in a manner as shown in FIG. 5(D) in case the SDRAM 18 adopts the 16 bit width, and changes in a manner as shown in FIG. 6(D) in case the SDRAM 18 adopts the 32 bit width

The F/F circuit 36 is enabled in a period during which an output of the inverter 34 indicates an H level, and latches the added value outputted from the selector 32 in response to rising of the clock CLK2. The latched added value is outputted from the address designating circuit 12a or 14a as the integrated address.

Accordingly, a value of lower 12 bits of the integrated address changes in a manner as shown in FIG. 5(E) when the mode information indicates “MD16”, and changes in a manner as shown in FIG. 6(E) when the mode information indicates “MD32”. A burst length of the SDRAM 18 is set to “4” without respect to the bit width, the value of the lower 12 bits is updated every four cycles of the clock CLK1 in either case of FIG. 5(E) or FIG. 6(E).

The address converting circuit 16c is configured as shown in FIG. 4. A selector 40 selects any one of the integrated addresses outputted from the address designating circuit 12a and the integrated addresses outputted from the address designating circuit 12b. The selected integrated addresses are applied to a distributor 46 via F/F circuits 42 and 44 each of which executes a latching operation in response to the clock CLK2.

The distributor 46 applies to a bank/row address generating circuit 48 a value of upper 17 bits or upper 16 bits out of a value of 26 bits equivalent to each integrated address. The value of the upper 17 bits is applied to the bank/row address generating circuit 48 corresponding to the mode information of “MD16”, and the value of the upper 16 bits is applied to the bank/row address generating circuit 48 corresponding to the mode information of “MD32”.

The bank/row address generating circuit 48 generates the bank address and the row address based on the applied 17 bit value or 16 bit value. The generated bank address and row address are outputted to the SDRAM 18 via an F/F circuit 50 which executes a latching operation in response to the clock CLK1.

Also, the distributor 46 applies a value of lower 10 bits out of the 26 bits equivalent to each integrated address to one input terminal of a selector 54, and applies a value of lower 9 bits out of the 26 bits equivalent to each integrated address to a combiner 52. The combiner 52 appends one bit value indicating “0” to the bottom of the applied 9 bit value so as to apply thus obtained 10 bit value(=twice the 9 bit value outputted from the distributor 46) to another terminal of the selector 54.

The selector 54 selects the 10 bit value applied from the combiner 52 corresponding to the mode information of “MD16” whereas selects the 10 bit value applied from the distributor 46 corresponding to the mode information of “MD32”. Thus selected 10 bit value is outputted as the column address via an F/F circuit 56 which executes a latching operation in response to the clock CLK2 and an F/F circuit 58 which executes a latching operation in response to the clock CLK1.

Accordingly, in case the SDRAM 18 is the memory which adopts the 16 bit width, the column address is outputted from the F/F circuit 58 in a manner as shown in FIG. 5(F), based on the integrated address shown in FIG. 5(E). In contrast, in case the SDRAM 18 is the memory which adopts the 32 bit width, the column address is outputted from the F/F circuit 58 in a manner as shown in FIG. 6(F), based on the integrated address shown in FIG. 6(E).

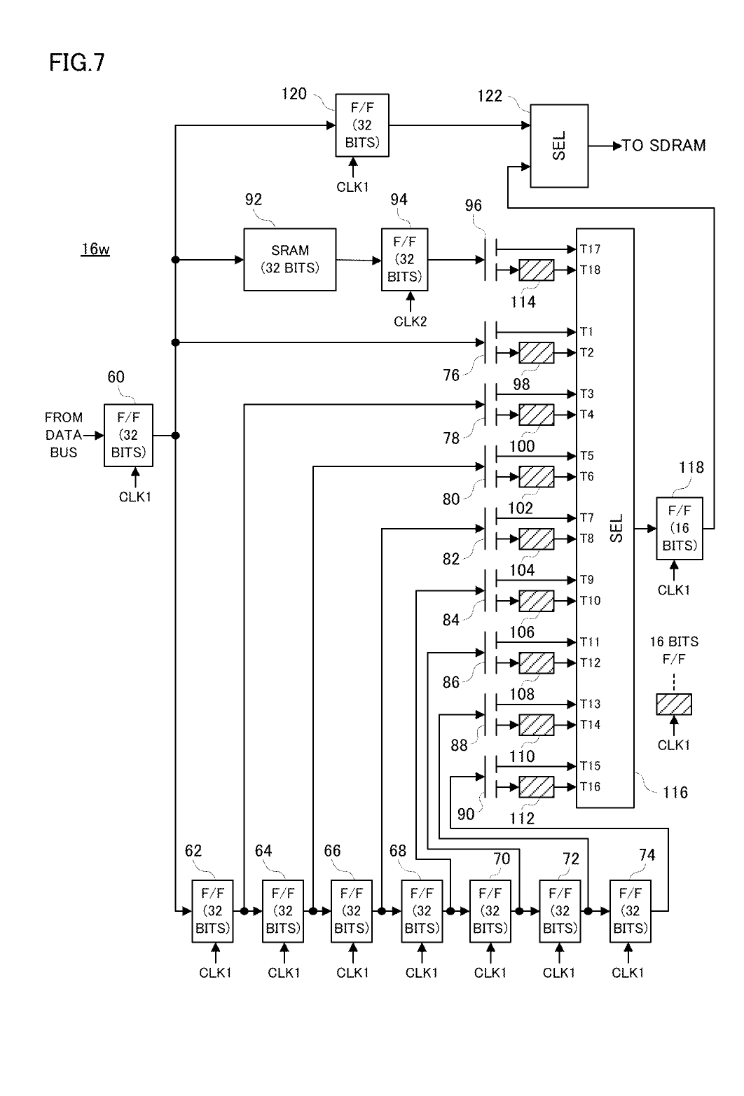

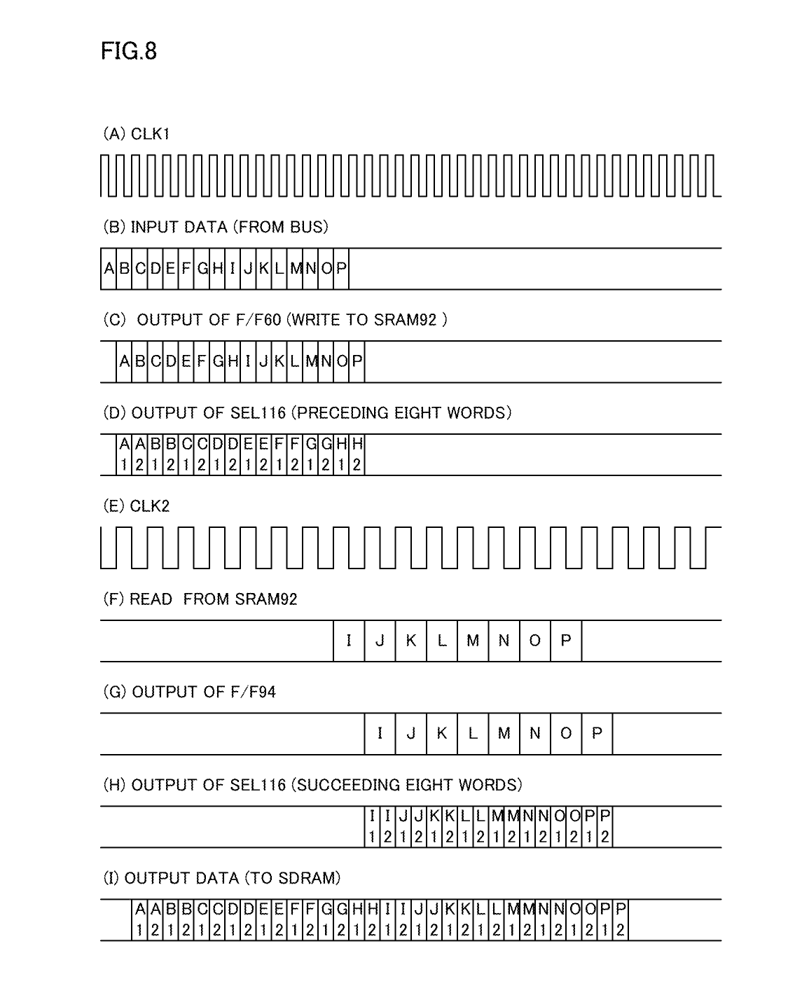

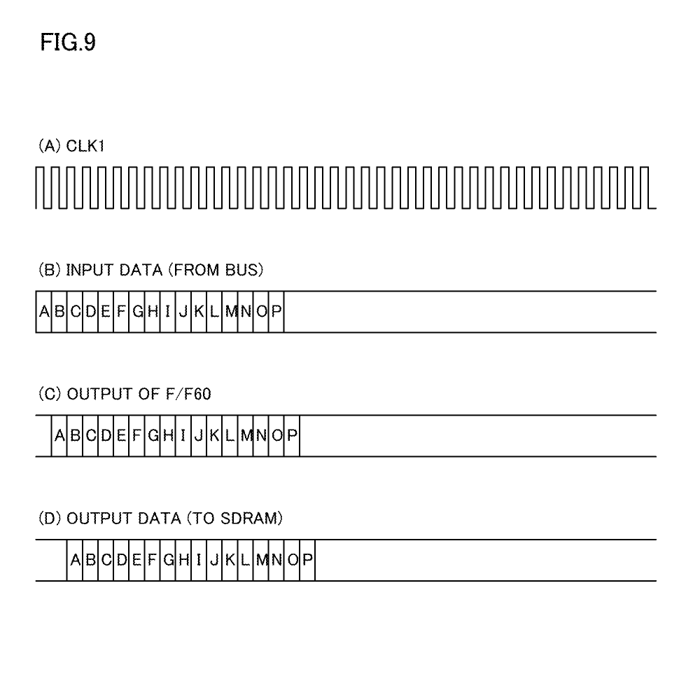

The write data transfer circuit 16w is configures as shown in FIG. 7. The data transferred via the bus BS1 is data of 16 words each word having a 32 bit width, which is applied to an F/F circuit 60 in a manner as shown in FIG. 8(B) or FIG. 9(B) in synchronization with the clock CLK1 shown in FIG. 8(A) or FIG. 9(A). The F/F circuit 60 has a 32 bit width and latches the inputted data in response to the clock CLK1. The latched data is outputted from the F/F circuit 60 at a timing shown in FIG. 8(C) or FIG. 9(C).

It is noted that, as a matter of convenience, any one of reference signs “A” to “P” is assigned to each of the 16 words.

Data A corresponding to a first word outputted from the F/F circuit 60 is divided to partial data A1 and A2 by a distributor 76. The partial data A1 is equivalent to data of upper 16 bits, and the partial data A2 is equivalent to data of lower 16 bits. The partial data A1 is directly inputted to a terminal T1 of a selector 116 whereas the partial data A2 is inputted to a terminal T2 of the selector 116 via ail F/F circuit 98. The F/F circuit 98 has a 16 bit width and executes a latching operation in response to the clock CLK1. Accordingly, the partial data A2 is inputted to the selector 116 after a delay equivalent to one cycle of the clock CKL1.

Data B to H corresponding to a second word to an eighth word outputted from the F/F circuit 60 are applied to seven F/F circuits 62 to 74 which are serially connected. Each of the F/F circuits 62 to 74 has a 32 bit width and latches the data B to H corresponding to the second word to the eighth word in response to the clock CLK1.

A distributor 78 divides the data B corresponding to the second word outputted from the F/F circuit 62 into partial data B1 equivalent to data of upper 16 bits and partial data B2 equivalent to data of lower 16 bits. The partial data B1 is directly inputted to a terminal T3 of the selector 116. On the other hand, the partial data B2 is inputted to a terminal T4 of the selector 116 after a delay equivalent to one cycle of the clock CKL1 via an F/F circuit 100 having a 16 bit width.

A distributor 80 divides the data C corresponding to the third word outputted from the F/F circuit 64 into partial data Cl equivalent to data of upper 16 bits and partial data C2 equivalent to data of lower 16 bits. The partial data C 1 is directly inputted to a terminal T5 of the selector 116. On the other hand, the partial data C2 is inputted to a terminal T6 of the selector 116 after a delay equivalent to one cycle of the clock CKL1 via an F/F circuit 102 having a 16 bit width.

A distributor 82 divides the data D corresponding to the fourth word outputted from the F/F circuit 66 into partial data D1 equivalent to data of upper 16 bits and partial data D2 equivalent to data of lower 16 bits. The partial data D1 is directly inputted to a terminal T7 of the selector 116. On the other hand, the partial data D2 is inputted to a terminal T8 of the selector 116 after a delay equivalent to one cycle of the clock CKL1 via an F/F circuit 104 having a 16 bit width.

A distributor 84 divides the data E corresponding to the fifth word outputted from the F/F circuit 68 into partial data El equivalent to data of upper 16 bits and partial data E2 equivalent to data of lower 16 bits. The partial data El is directly inputted to a terminal T9 of the selector 116. On the other hand, the partial data E2 is inputted to a terminal T10 of the selector 116 after a delay equivalent to one cycle of the clock CKL1 via an F/F circuit 106 having a 16 bit width.

A distributor 86 divides the data F corresponding to the sixth word outputted from the F/F circuit 70 into partial data F1 equivalent to data of upper 16 bits and partial data F2 equivalent to data of lower 16 bits. The partial data F1 is directly inputted to a terminal T11 of the selector 116. On the other hand, the partial data F2 is inputted to a terminal T12 of the selector 116 after a delay equivalent to one cycle of the clock CKL1 via an F/F circuit 108 having a 16 bit width.

A distributor 88 divides the data. G corresponding to the seventh word outputted from the F/F circuit 72 into partial data G1 equivalent to data of upper 16 bits and partial data G2 equivalent to data of lower 16 bits. The partial data G1 is directly inputted to a terminal T13 of the selector 116. On the other hand, the partial data G2 is inputted to a terminal T14 of the selector 116 after a delay equivalent to one cycle of the clock CKL1 via an F/F circuit 110 having a 16 bit width.

A distributor 90 divides the data H corresponding to the eighth word outputted from the F/F circuit 74 into partial data H1 equivalent to data of upper 16 bits and partial data H2 equivalent to data of lower 16 bits. The partial data H1 is directly inputted to a terminal T15 of the selector 116. On the other hand, the partial data H2 is inputted to a terminal T16 of the selector 116 after a delay equivalent to one cycle of the clock CKL1 via an F/F circuit 112 having a 16 bit width.

The selector 116 sequentially selects the terminals T1 to T16 for each time the clock CLK1 rises. Consequently, the partial data A1 to H2 are outputted from the selector 116 at a timing shown in FIG. 8(D).

The data A to P corresponding to the 16 words outputted from the F/F circuit 60 are also written into an SRAM 92. Out of these data, the data I to P corresponding to a ninth word to a 16th word are read out from the SRAM 92 at a timing shown in FIG. 8(F) after a delay equivalent to three cycles of the clock CLK2 shown in FIG. 8(E).

An F/F circuit 94 having a 32 bit width is connected to an output terminal of the SRAM 92. The F/F circuit 94 executes a latching operation in response to the clock CLK2. Accordingly, the dada I to P corresponding to eight words read out from the SRAM 92 is outputted from the F/F circuit 94 at a timing shown in FIG. 8(G).

A distributor 96 divides the data of each word outputted from the F/F circuit 94 into partial data of upper 16 bits and partial data of lower 16 bits. The data I corresponding to the ninth word is divided into partial data I1 and I2, the data J corresponding to the 10th word is divided into partial data J1 and J2, the data K corresponding to the 11th word is divided into partial data K1 and K2, the data L corresponding to the 12th word is divided into partial data L1 and L2, the data M corresponding to the 13th word is divided into partial data M1 and M2, the data N corresponding to the 14th word is divided into partial data N1 and N2, the data O corresponding to the 15th word is divided into partial data O1 and O2, and the data P corresponding to the 16th word is divided into partial data P1 and P2.

The partial data of upper 16 bits is directly inputted to a terminal T17 of the selector 116. On the other hand, the partial data of lower 16 bits is inputted to a terminal T18 of the selector 116 after a delay equivalent to one cycle of the clock CLK1 via an F/F circuit 114 having a 16 bit width.

On completion of selecting the terminal T16, the selector 116 alternately selects the terminals T17 and T18 every time the clock CLK1 rises. Consequently, the partial data I1 to P2 are outputted from the selector 116 at a timing shown in FIG. 8(H).

An F/F circuit 118 has a 16 bit width and latches the partial data A1 to P2 outputted from the selector 116 in response to the clock CLK1. Consequently, the partial data A1 to P2 are outputted from the F/F circuit 118 at a timing shown in FIG. 8(I).

The data A to P corresponding to the 16 words outputted from the F/F circuit 60 are also applied to an F/F circuit 120 having a 32 bit width. The F/F circuit 120 latches the applied data A to P in response to the clock CLK1. The latched data A to P are outputted from the F/F circuit 120 at a timing shown in FIG. 9(D).

A selector 122 selects the partial data A1 to P2 outputted from the F/F circuit 118 when the SDRAM 18 is the memory adopting the 16 bit width whereas selects the data A to P outputted from the F/F circuit 120 when the SDRAM 18 is the memory adopting the 32 bit width. The selected data is outputted to the SDRAM 18.

It is noted that the data A to P shown in FIG. 8(B) are inputted at a timing shown in FIG. 5(G) with respected to the column addresses shown in FIG. 5(F). Furthermore, the data A1 to P2 shown in FIG. 8(I) are outputted at a timing shown in FIG. 5(H) with respected to the column addresses shown in FIG. 5(F). Even more, the data A to P shown in FIG. 9(B) are inputted at a timing shown in FIG. 6(G) with respected to the column addresses shown in FIG. 6(F). Moreover, the data A to P shown in FIG. 9(D) are outputted at a timing shown in FIG. 6(H) with respected to the column addresses shown in FIG. 6(F).

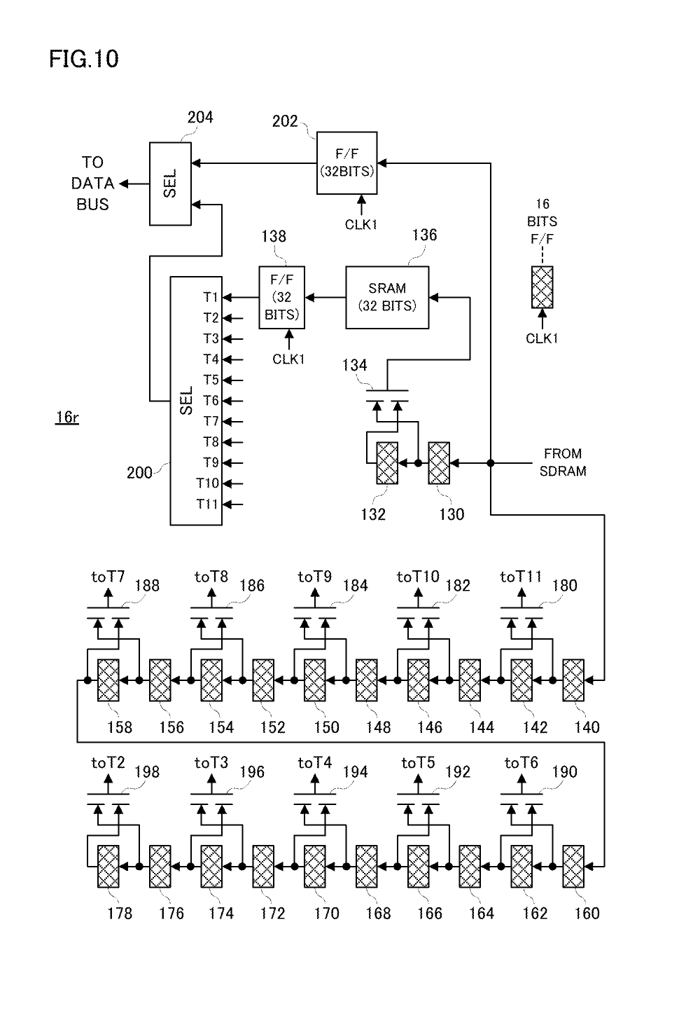

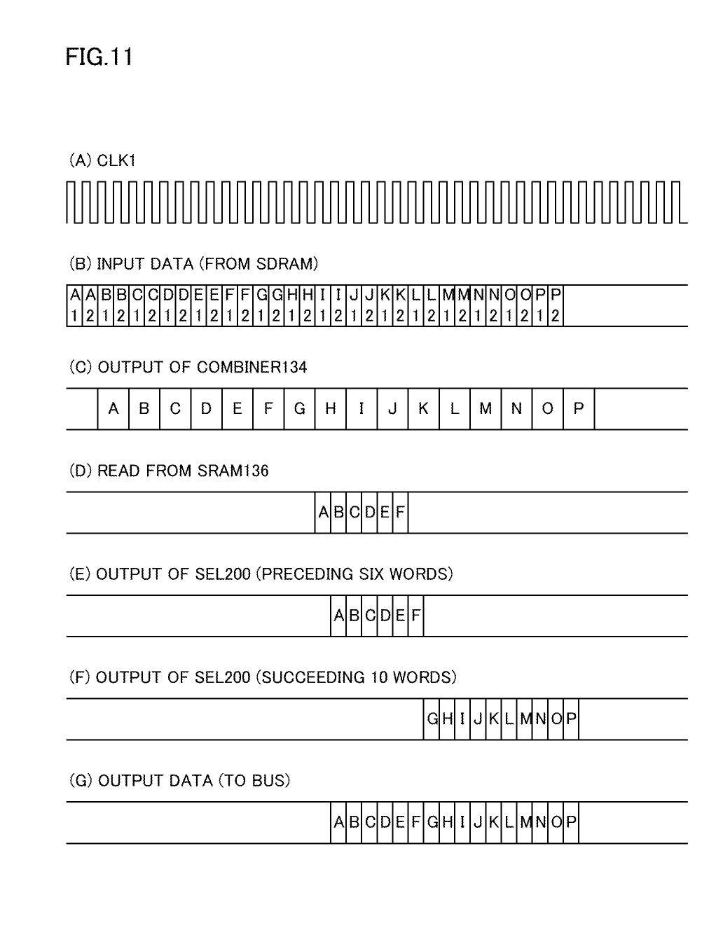

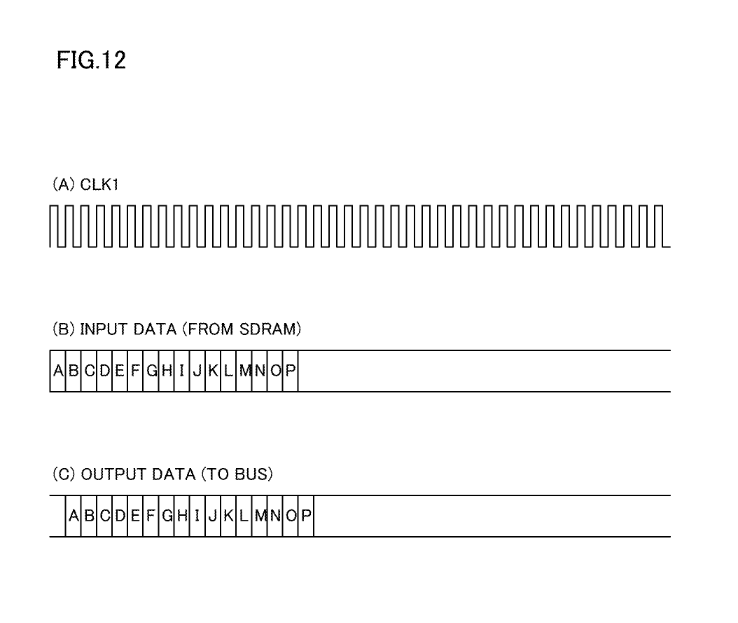

The read data transfer circuit 16r is configured as shown in FIG. 10. In case the SDRAM 18 is the memory adopting the 16 bit width, the above described data A1 to P2 corresponding to 32 words are read out from the SDRAM 18. The read data A1 to P2 are inputted in a manner as shown in FIG. 11(B) in synchronization with the clock CLK1 shown in FIG. 11(A). On the other hand, in case the SDRAM 18 is the memory adopting the 32 bit width, the above described data A to P corresponding to 16 words are read out from the SDRAM 18. The read data A to P are inputted in a manner as shown in FIG. 12(B) in synchronization with the clock CLK1 shown in FIG. 12(A).

Taking notice of a case where the SDRAM 18 is the memory adopting the 16 bit width, the data A1 to P2 inputted from the SDRAM 18 are applied to serially connected F/F circuits 130 to 132. Each of the F/F circuits 130 to 132 has a 16 bit width and latches the data A1 to P2 in response to the clock CLK1. Data simultaneously outputted from the F/F circuits 130 to 132 are combined by a combiner 134 every two cycles of the clock CLK2. Therefore, created are combined data A to P corresponding to 16 words each word having a 32 bit width.

Here, the combined data A is equivalent to data in which the data A1 and A2 are respectively arranged into upper 16 bits and lower 16 bits, and the combined data B is equivalent to data in which the data B1 and B2 are respectively arranged into upper 16 bits and lower 16 bits. The combined data C is equivalent to data in which the data Cl and C2 are respectively arranged into upper 16 bits and lower 16 bits, and the combined data D is equivalent to data in which the data D1 and D2 are respectively arranged into upper 16 bits and lower 16 bits.

The combined data E is equivalent to data in which the data El and E2 are respectively arranged into upper 16 bits and lower 16 bits, and the combined data F is equivalent to data in which the data F1 and F2 are respectively arranged into upper 16 bits and lower 16 bits. The combined data G is equivalent to data in which the data G1 and G2 are respectively arranged into upper 16 bits and lower 16 bits, and the combined data H is equivalent to data in which the data H1 and H2 are respectively arranged into upper 16 bits and lower 16 bits.

The combined data I is equivalent to data in which the data I1 and I2 are respectively arranged into upper 16 bits and lower 16 bits, and the combined data J is equivalent to data in which the data J1 and J2 are respectively arranged into upper 16 bits and lower 16 bits. The combined data K is equivalent to data in which the data K1 and K2 are respectively arranged into upper 16 bits and lower 16 bits, and the combined data L is equivalent to data in which the data L1 and L2 are respectively arranged into upper 16 bits and lower 16 bits.

The combined data M is equivalent to data in which the data M1 and M2 are respectively arranged into upper 16 bits and lower 16 bits, and the combined data N is equivalent to data in which the data N1 and N2 are respectively arranged into upper 16 bits and lower 16 bits. The combined data O is equivalent to data in which the data O1 and O2 are respectively arranged into upper 16 bits and lower 16 bits, and the combined data P is equivalent to data in which the data P1 and P2 are respectively arranged into upper 16 bits and lower 16 bits.

The combined data A to P are outputted from the combiner 134 at a timing shown in FIG. 11(C), and the combined data A to F of them are written into an SRAM 136. The data A to F stored in the SRAM 136 are read out in response to the clock CLK1 at a timing shown in FIG. 11(D) i.e. at a timing the combined data H is outputted from the combiner 134. An F/F circuit 138 latches the combined data A to F outputted from the SRAM 136 in response to the clock CLK1, and outputs the latched combined data A to F after a delay equivalent to one cycle of the clock CLK1. The outputted combined data A to F are outputted at a timing shown in FIG. 11(E) via a terminal T1 of a selector 200.

The data A1 to P2 inputted from the SDRAM 18 are also applied to twenty F/F circuits 140 to 178 which are serially connected. Each of the F/F circuits 140 to 178 has a 16 bit width and latches the data A1 to P2 corresponding to 32 words in response to the clock CLK1.

Data simultaneously outputted from the F/F circuits 140 to 142 are combined by a combiner 180 every two cycles of the clock CLK1, and thus created combined data is applied to a terminal T11 of the selector 200. Data simultaneously outputted from the F/F circuits 144 to 146 are combined by a combiner 182 every two cycles of the clock CLK1, and thus created combined data is applied to a terminal T10 of the selector 200.

Data simultaneously outputted from the F/F circuits 148 to 150 are combined by a combiner 184 every two cycles of the clock CLK1, and thus created combined data is applied to a terminal T9 of the selector 200. Data simultaneously outputted from the F/F circuits 152 to 154 are combined by a combiner 186 every two cycles of the clock CLK1, and thus created combined data is applied to a terminal T8 of the selector 200.

Data simultaneously outputted from the F/F circuits 156 to 158 are combined by a combiner 188 every two cycles of the clock CLK1, and thus created combined data is applied to a terminal T7 of the selector 200. Data simultaneously outputted from the F/F circuits 160 to 162 are combined by a combiner 190 every two cycles of the clock CLK1, and thus created combined data is applied to a terminal T6 of the selector 200.

Data simultaneously outputted from the F/F circuits 164 to 166 are combined by a combiner 192 every two cycles of the clock CLK1, and thus created combined data is applied to a terminal T5 of the selector 200. Data simultaneously outputted from the F/F circuits 168 to 170 are combined by a combiner 194 every two cycles of the clock CLK1, and thus created combined data is applied to a terminal T4 of the selector 200.

Data simultaneously outputted from the F/F circuits 172 to 174 are combined by a combiner 196 every two cycles of the clock CLK1, and thus created combined data is applied to a terminal T3 of the selector 200. Data simultaneously outputted from the F/F circuits 176 to 178 are combined by a combiner 198 every two cycles of the clock CLK1, and thus created combined data is applied to a terminal T2 of the selector 200.

After outputting the data F applied to the terminal T1, the selector 200 sequentially selects the terminal T2 to T11 every time the clock CLK rises. Consequently, combined data G to P respectively created by the combiners 198 to 180 are outputted from the selector 200 at a timing shown in FIG. 11(F).

A selector 204 selects the selector 200 when the SDRAM 18 is the memory adopting the 16 bit width. The combined data A to P outputted from the selector 200 are outputted to the bus BS1 in a manner as shown in FIG. 11(G).

Taking notice of a case where the SDRAM 18 is the memory adopting the 32 bit width, the data A to P inputted from the SDRAM 18 are applied to an F/F circuit 202 having a 32 bit width. The F/F circuit 202 latches the data A to P in response to the clock CLK1 and applies the latched data A to P to the selector 204. The selector 204 selects the ET circuit 202 when the SDRAM 18 is the memory adopting the 32 bit width. Accordingly, the data A to P applied from the F/F circuit 202 is outputted to the bus BS1 in a manner as shown in FIG. 12(C).

It is noted that the data A1 to P2 shown in FIG. 11(B) are inputted at a timing shown in FIG. 5(I) with respect to the column addresses shown in FIG. 5(F). Furthermore, the data A to P shown in FIG. 11(G) are outputted at a timing shown in FIG. 5(J) with respect to the column addresses shown in FIG. 5(F). Even more, the data A to P shown in FIG. 12(B) are inputted at a timing shown in FIG. 6(I) with respect to the column addresses shown in FIG. 6(F). Moreover, the data A to P shown in FIG. 12(C) are outputted at a timing shown in FIG. 6(J) with respect to the column addresses shown in FIG. 6(F).

As understood from the above description, the counter 24 outputs seven count values (=K of address coefficients) corresponding to the mode information “MD32” whereas outputs 15 count values (=L of address coefficients) corresponding to the mode information “MD16”. The distributor 26 and the combiner 28 convert each count value outputted from the counter 24 into a value of ½(=1/M). The selector 32 selects added values (=address information) based on the count values outputted from the counter 24 corresponding to the mode information “MD32” whereas selects added values based on the values outputted from the combiner 28 corresponding to the mode information “MD16”. Each of a plurality of addresses provided in the SDRAM 18 has a bit width equivalent to any one of 32 bits (=N bits) and 16 bits (=N/M bits). The F/F circuit 36 outputs the added values selected by the selector 32 as the integrated addresses in order to access the SDRAM 18.

Thus, when the mode information indicates “MD32”, the integrated addresses are created based on the seven count values outputted from the counter 24. In contrast, when the mode information indicates “MD16”, each of the 15 count values outputted from the counter 24 is converted in to a value of ½, and the integrated addresses are created based on the converted values. On the other hand, the address of the SDRAM 18 has the bit width equivalent to 32 bits or 16 bits.

Accordingly, by setting the mode information into “MD32” for the SDRAM 18 having the 32 bit width and setting the mode information into “MD16” for the SDRAM 18 having the 16 bit width, an adoptive accessing operation is realized for SDRAMs each of which has a different bit width, and therefore, memory access performance is improved.

It is noted that every electronic device, such as a digital camera or an audio player, which processes data using an SDRAM is assumed as the data processing apparatus 10 of this embodiment.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A memory accessing device, comprising:
a generator which generates K (K: an integer equal to or more than two) of address coefficients corresponding to a first mode whereas generates L (L: an integer more than K) of address coefficients corresponding to a second mode;
a first converter which converts each value of the address coefficients generated by said generator into a value of 1/M (M: an integer equal to or more than two);
a creator which creates address information based on the address coefficients generated by said generator corresponding to the first mode whereas creates address information based on address coefficients converted by said first converter corresponding to the second mode; and
an outputter which outputs the address information created by said creator in order to access a memory provided with a plurality of addresses each of which has a bit width equivalent to any one of N bits and N/M bits.

2. A memory accessing device according to claim 1, wherein the first mode is corresponding to a memory provided with addresses each having a bit width equivalent to the N bits, and the second mode is corresponding to a memory provided with addresses each having a bit width equivalent to the N/M bits.

3. A memory accessing device according to claim 1, wherein the L indicates a value belonging to a range from M times to M+1 times the value of the K.

4. A memory accessing device according to claim 1, wherein said memory adopts a burst access system, and said outputter includes a latch circuit which latches the address information created by said creator with a period corresponding to a burst length of said memory

5. A memory accessing device according to claim 4, further comprising:
a detector which detects address coefficients becoming the basis of the address information outputted from said outputter;
a second converter which converts each value of the address coefficients detected by said detector into a value of M times; and
a selector which selects the address coefficients detected by said detector corresponding to the first mode whereas selects the address coefficients converted by said second converter corresponding to the second mode.

6. A memory accessing device according to claim 5, wherein each of the plurality of addresses provided in said memory has a column address, and each of the address coefficients selected by said selector is equivalent to a coefficient to specify the column address of an access destination.

7. A memory accessing device according to claim 5, further comprising:
a divider which divides data having a bit width equivalent to the N bits for each word into partial data having a bit width equivalent to the N/M bits for each word; and
a data outputter which outputs the partial data divided by said divider to said memory.

8. A memory accessing device according to claim 5, further comprising:
a combiner which combines data having a bit width equivalent to the N/M bits for each word, which is read out from said memory, so as to create combined data having a bit width equivalent to the N bits for each word; and
an outputter which outputs the combined data created by said creator.

9. A memory accessing method which is executed by a memory accessing device, comprising:
a generating step of generating K (K: an integer equal to or more than two) of address coefficients corresponding to a first mode whereas generating L (L: an integer more than K) of address coefficients corresponding to a second mode;
a first converting step of converting each value of the address coefficients generated by said generating step into a value of 1/M (M: an integer equal to or more than two);
a creating step of creating address information based on the address coefficients generated by said generating step corresponding to the first mode whereas creating address information based on address coefficients converted by said first converting step corresponding to the second mode; and
an outputting step of outputting the address information created by said creating step in order to access a memory provided with a plurality of addresses each of which has a bit width equivalent to any one of N bits and N/M bits.
